(19) United States
(12) Patent Application Publication
(10) Pub. No.: US 2012/0281377 A1
(43) Pub. Date: Nov. 8, 2012

(54) VIAS FOR MITIGATING PAD DELAMINATION

(76) Inventor: Naveen Kini, San Jose, CA (US)

(21) Appl. No.: 13/102,398

(22) Filed: May 6, 2011

(51) Int. Cl. H05K 1/18

(52) U.S. Cl. 361/767; 174/262

(57) ABSTRACT

A signal carrier medium is disclosed including support vias for maintaining laminated portions of the signal carrier medium together. The signal carrier medium includes metal portions such as a contact pad. The metal portions may have one or more adjacent support vias for dissipating stresses which build in the metal portions.

### BACKGROUND

1. Field

Embodiments of the present technology relate to a signal carrier medium for supporting an electronic component such as for example a flash memory semiconductor device.

2. Description of the Related Art

The strong growth in demand for portable consumer electronics is driving the need for high-capacity storage devices. Non-volatile semiconductor memory devices, such as flash memory storage cards and devices, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

Electronic components such as flash memory devices may be mounted on a signal carrier medium such as a printed circuit board (“PCB”). In general, a PCB may include one or more layers of a dielectric substrate having a conductive layer laminated onto one or both surfaces. Using techniques such as photolithography, conductance patterns may be defined in the conductive layers. The conductance patterns include electrical contact pads to which electrical contacts are soldered, and electrical traces for communicating signals and power/ground voltage to and from the electronic components on the PCB.

Although it is known to form conductance patterns with very fine electrical traces, owing to the number of connections required on modern-day PCBs, there may not be enough surface area in a single-layered PCB to affect the required signal and voltage (power and ground) transfer. It is therefore known to form PCBs with a plurality of conductive layers, each separated by a dielectric substrate. Modern PCBs may for example have as many as twenty or more layers. In order to communicate signals and power/ground voltages between the various layers, holes, known as vias, are formed through respective layers. Once formed, the vias are either plated or filled with a metal to provide electrical communication between adjacent layers. FIG. 1 is a prior art top view of a conventional PCB 50 including a conductance pattern having contact pads 52 and electrical traces 54. The PCB 50 further includes vias 58 for transferring electrical signals to different levels of the PCB. The PCB shown is by way of example only, and may include greater or fewer contact pads 52, electrical traces 54 and/or vias 58.

One problem with PCBs and other signal carrier media is that one or more of the conductive layers can delaminate from the adjacent dielectric layer. For example, after the conductance pattern is defined, one or more of the electrical contact pads may be subjected to mechanical and/or thermal stresses, causing the pads to delaminate. Delamination of the contact pads or other portions of the signal carrier medium is a common failure mode seen during semiconductor package mechanical reliability testing, such as drop testing, bend testing and temperature cycling.

### BRIEF DESCRIPTION OF THE DRAWINGS

FIG. 1 is a prior art top view of a conventional PCB including contact pads, electrical traces and vias.

FIG. 2 is a flowchart showing construction of a memory device according to embodiments of the present technology.

FIG. 3 is a top view of a portion of a signal carrier medium according to an embodiment of the present technology during a first stage of fabrication.

FIG. 4 is a cross-sectional edge view of a signal carrier medium according to an embodiment of the present technology during the first stage of fabrication.

FIG. 5 is a top view of a portion of a signal carrier medium according to an embodiment of the present technology during a second stage of fabrication.

FIG. 6 is a cross-sectional edge view of a signal carrier medium according to an embodiment of the present technology during the second stage of fabrication.

FIG. 7 is an enlarged top view of a portion of a signal carrier medium including an electrical contact and support vias according to an embodiment of the present technology.

FIG. 8 is an enlarged cross-sectional view of the signal carrier medium including the electrical contact and support via shown in FIG. 7.

FIG. 8A is an enlarged cross-sectional view of an alternative embodiment of the signal carrier medium including the electrical contact and support via.

FIG. 9 is a top view of a portion of a signal carrier medium according to an embodiment of the present technology during a third stage of fabrication.

FIG. 10 is an enlarged cross-sectional edge view of a signal carrier medium according to an embodiment of the present technology during the third stage of fabrication.

FIG. 11 is a top view of a portion of a signal carrier medium according to an embodiment of the present technology during a fourth stage of fabrication.

FIG. 12 is an enlarged cross-sectional edge view of a signal carrier medium according to an embodiment of the present technology during the fourth stage of fabrication.

FIG. 13 is a top view of a portion of a signal carrier medium and electronic component according to an embodiment of the present technology during a fifth stage of fabrication.

FIG. 14 is an enlarged cross-sectional edge view of a signal carrier medium according to an embodiment of the present technology during the fifth stage of fabrication.

FIG. 14A is an enlarged cross-sectional edge view of an alternative signal carrier medium and memory die according to an embodiment of the present technology during the fifth stage of fabrication.

FIG. 15 is a top view of a portion of a signal carrier medium and electronic component according to an alternative embodiment of the present technology

FIG. 16 is an enlarged cross-sectional edge view of a signal carrier medium and electronic component according to the alternative embodiment of FIG. 15.

FIG. 17 is a cross-sectional edge view of a finished semiconductor package according to embodiments of the present technology.

FIG. 18 is a bottom view of a portion of a signal carrier medium according to an embodiment of the present technology during fabrication.

FIG. 19 is a cross-sectional view of a multi-layer signal carrier medium according to embodiments of the present technology.

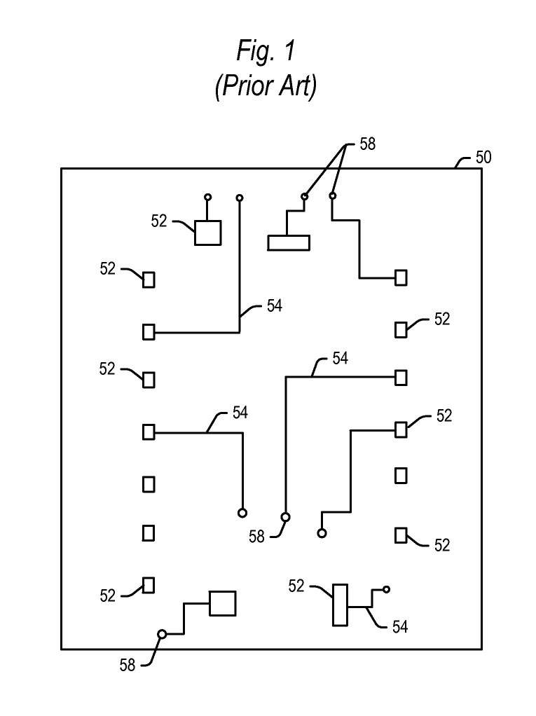

### DETAILED DESCRIPTION

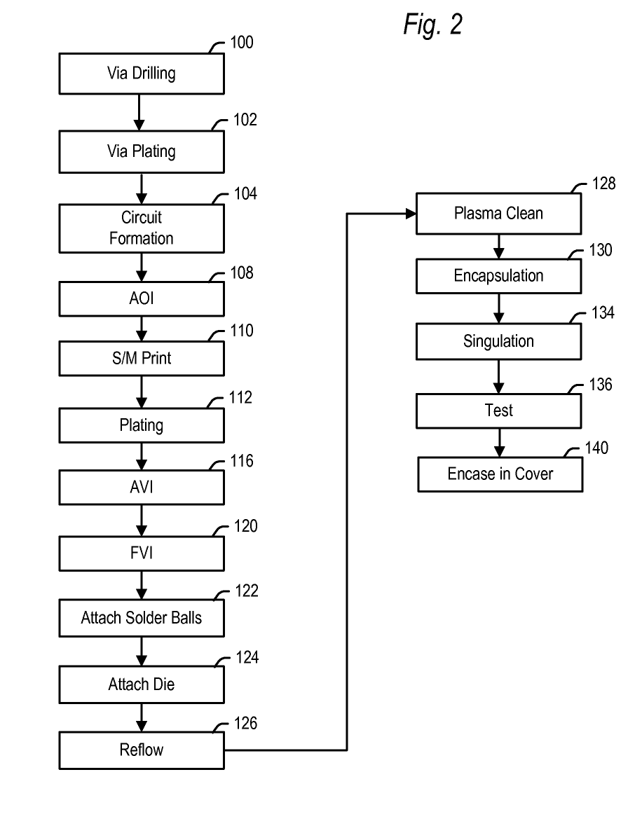

Embodiments of the invention will now be described with reference to FIGS. 2 through 19 which relate to a signal carrier medium including support vias for maintaining laminated portions of the signal carrier medium together. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

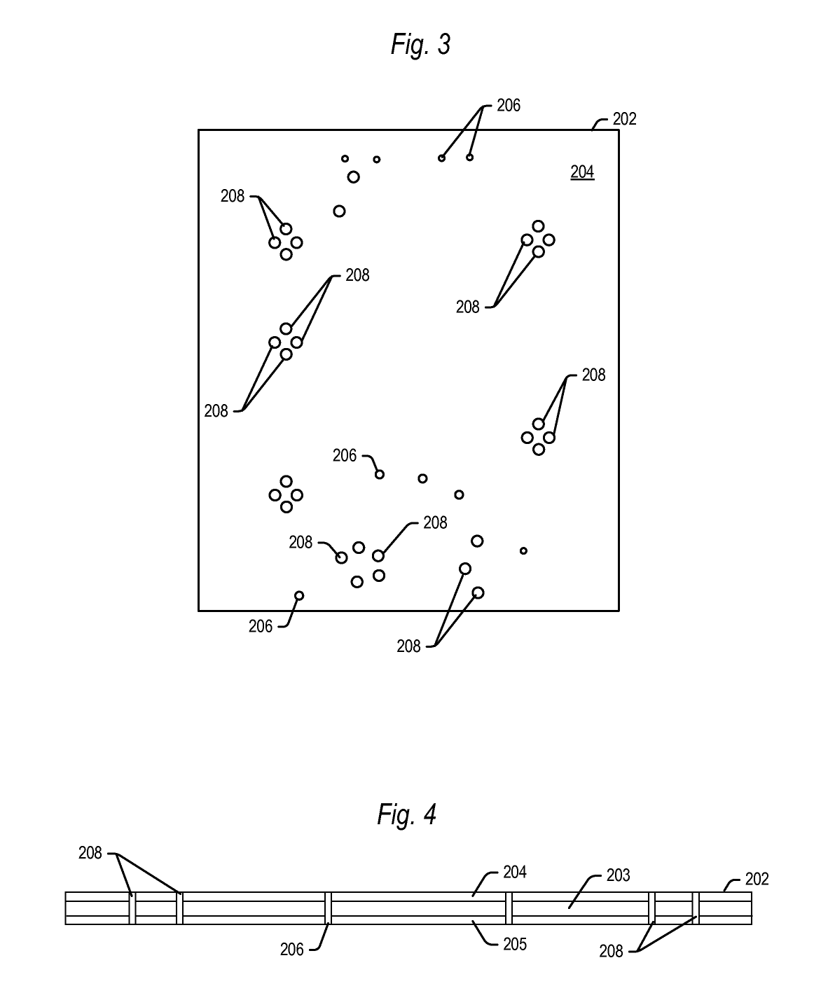

An embodiment of the present technology will now be explained with reference to the flowchart of FIG. 2, and the top and edge views of FIGS. 3 through 19. The present technology may be implemented in a variety of signal carrier media 202. One example of a signal carrier medium 202 is a PCB. A PCB may include a variety of conductive contacts as explained below for receiving electronic components. An example of an electronic component that may be mounted on the PCB is a flash memory semiconductor device as explained below. Another example of a signal carrier medium is a substrate used in a flash memory semiconductor device. In these embodiments, a substrate may be used to mount one or more semiconductor die in a flash memory semiconductor device, and to transfer signals to/from the one or more semiconductor die in a flash memory semiconductor device. In a further example, the signal carrier medium may be a tape automated bonded (TAB) tape.

Where the signal carrier medium is a PCB or a substrate, the signal carrier medium 202 may be formed of a core 203 having top conductive layer 204 and bottom conductive layer 205 as seen in FIG. 4. The core may be formed of various dielectric materials such as for example, polyimide laminates, epoxy resins including FR4 and FR5, bismaleimide triazine (BT), and the like. Although not critical to the present invention, the core may have a thickness of between 40 microns (μm) to 200 μm, although the thickness of the core may vary outside of that range in alternative embodiments. The core may be ceramic or organic in alternative embodiments.

The conductive layers 204, 205 surrounding the core may be formed of copper or copper alloys, plated copper or plated copper alloys, copper plated steel, or other metals and materials known for use on PCB and substrate panels. The conductive layers may have a thickness of about 10 μm to 25 μm, although the thickness of the layers may vary outside of that range in alternative embodiments. In further embodiments, instead of a single conductive layer on opposite sides of the core, there may be multiple conductive layers on one or both sides of the core.

In a step 100, the signal carrier medium 202 is drilled to define vias 206 and 208 in the signal carrier medium 202 as shown in FIGS. 3 and 4. The vias 206, 208 (some of which are numbered in the figures) are by way of example, and the signal carrier medium may include many more or less vias 206, 208 than is shown in the figures, and they may be in different locations than are shown in the figures. Vias 206 are used to communicate electrical signals from one level of the signal carrier medium 202 to another, for example between the metal layers 204, 205 on core 203. Vias 206, which may be conventional vias, are referred to herein as signal communication vias. Vias 208 embody inventive aspects of the present technology and are referred to herein as support vias 208. As explained in greater detail below, support vias 208 are provided to maintain laminated portions of the signal carrier medium together. Further distinctions between vias 206 and 208 are explained hereinafter.

Support vias 208 may have the same size diameter as signal communication vias 206, or the vias 208 may be larger or smaller than the vias 206. In one embodiment, the support vias 208 may have a diameter of between 150 μm to 200 μm, though the diameter of vias 208 may be larger or smaller than that in further embodiments. Each of the support vias 208 may have the same diameter, or different support vias 208 may have different diameters from each other. Both vias 206 and 208 may be formed by mechanical drilling or with a laser, and each may be formed together prior to definition of a conductance pattern on the signal carrier medium 202 as explained hereinafter.

In the embodiments shown, the support via 208 is formed completely through the top and bottom surfaces of a signal carrier medium. However, it is understood that where a support via 208 is associated with a contact pad 210, or other metal portion, as explained below on the top surface 204 of the signal carrier medium, the support via may be formed down into the top surface 204 and only partially through the core 203. Similarly, where a metal portion is formed on the bottom surface 205, an associated support via 208 may be formed up through the bottom surface 205 and only partially through the core 203.

In step 102, the vias 206 and 208 may be plated. In embodiments, copper, gold, nickel, various alloys thereof, and other materials may be used to plate vias 206 and 208. In the embodiment shown for example in FIG. 4, the plating material of the vias 206 and 208 physically and electrically couples to the metal layers 204, 205 on both the top and bottom surfaces of signal carrier medium 202.

Conductance patterns are next formed in one or more of the conductive layers provided on the core in step 102. The conductance pattern is shown in the top layer in FIG. 4. It is understood that one or more of the remaining conductive layers may also have conductance patterns defined therein as well.

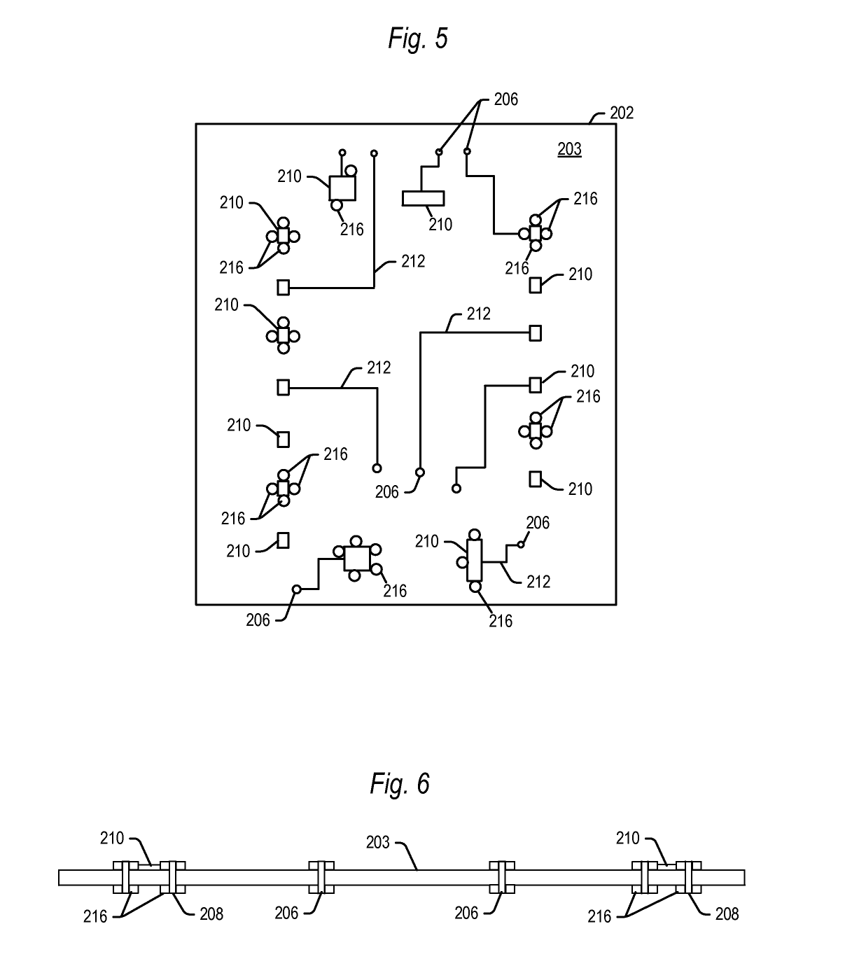

In step 104, the top and/or bottom metal layers 204, 205 may be etched or otherwise processed to remove portions of the metal layers and leave behind a conductance pattern as shown in the top and edge views of FIGS. 5 and 6. The conductance pattern includes electrical contact pads 210 and electrical traces 212 to and from the contact pads 210. Only some of the contact pads 210 and traces 212 are numbered in the figures. The contact pads 210 and traces 212 shown in the figures are by way of example only, and there may be greater or fewer contact pads 210 and traces 212 that are shown, and they may be provided in a wide variety of configurations. The contact pads 210 may be rectangular, circular, oval or other shapes, and may have a length, width and/or diameter of approximately 300 μm, though they may be larger or smaller than that in further embodiments.

The conductance pattern further includes via pads 216 that are left behind above and/or below the support vias 208. The signal communication vias 206 may or may not include via pads similar to via pads 216. The via pads 216 may be rectangular, circular, oval or other shapes, and may have a length, width and/or diameter of approximately 350 μm, though they may be larger or smaller than that in further embodiments. The conductance pattern in the various conductive layers of the signal carrier medium 202 may be formed by a variety of known processes, including for example various photolithographic processes.

The top view of FIG. 5 illustrates a distinction between support vias 208 and conventional vias such as signal communication vias 206. Signal communication vias are provided at an end of a trace 212, to carry the signal over trace 212 to another level of the signal carrier medium 202 (for example from the top layer 204 to the bottom layer 205). Conversely, support vias 208 are provided adjacent some or all of the contact pads 210. It is conceivable that, in embodiments, support vias 208 do carry signals to different levels of the signal carrier medium. However, the support vias 208 function to support the contact pads 210 to prevent delamination of the contact pads 210 from the core 203.

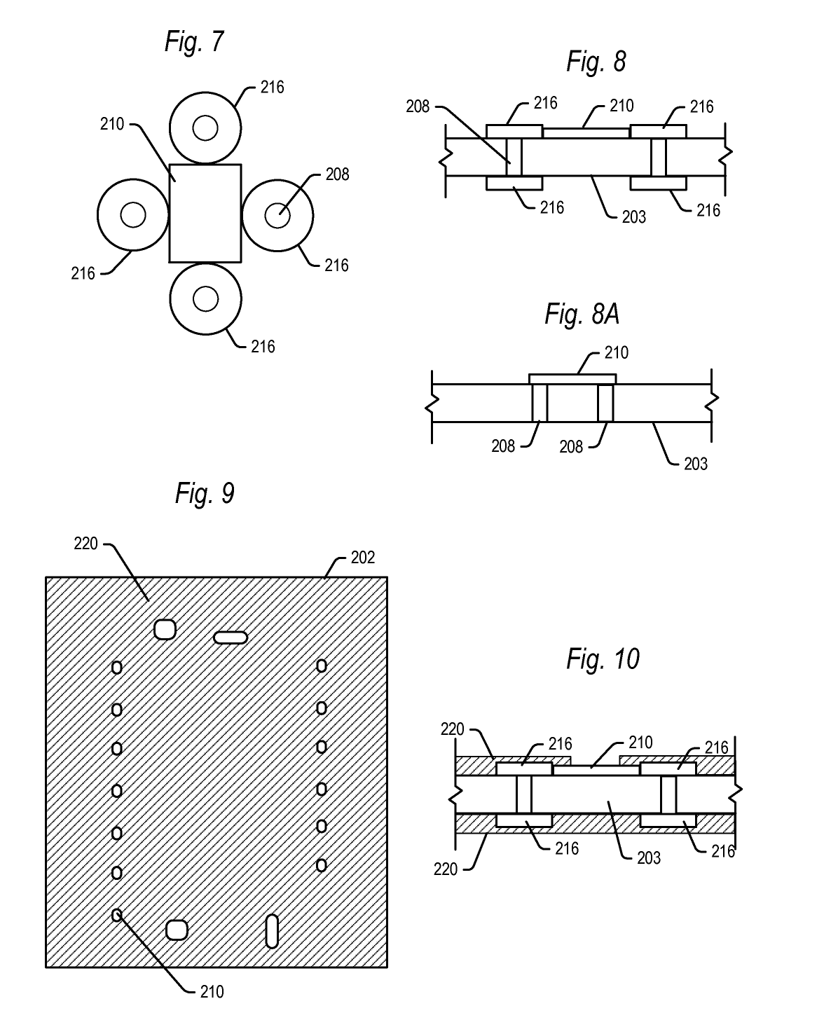

An enlarged top view and cross-sectional edge view of a portion of the signal carrier medium are shown in FIGS. 7 and 8, respectively. Each support via 208 has an associated contact pad 210. A single contact pad 210 may be surrounded by a group of support vias 208. In the example of FIG. 7, the contact pad 210 has four associated support vias 208, each having a via pad 216. However, in embodiments, the number of support vias 208 associated with a single contact pad 210 may vary between zero and five, though there may be greater than five support vias 208 associated with a single contact pad 210 in further embodiments. The support vias 208 lie adjacent an associated contact pad 210. In embodiments, the via pads 216 on the support vias 208 may be in contact with an associated contact pad 210, though a via pad 216 need not lie in direct contact with an associated contact pad 210 in further embodiments.

The support vias 208 provide support for an associated contact pad 210 and prevent delamination of the associated contact pad 210. In embodiments, when a support via 208 is plated, the plating material engages firmly against the walls of the core 203 defining the support via to fix the plating with respect to the core 203. The plating also affixes to the metal layer 204 and/or 205 on the top and bottom surfaces of the core 203. Thus, when the layers 204 and/or 205 are etched, the via pad 216 is also affixed to the plating of a support via 208. As the via pads 216 may lie in contact with an associated contact pad 210, the support vias 208 provide support for an associated contact pad 210.

In particular, in one embodiment, the support vias 208 serve to dissipate mechanical and/or thermal stresses which build in an associated contact pad 210, thus preventing delamination of the associated contact pad 210. Stresses may be generated from within the contact pads 210, or may result from external forces such as during solder ball and wire bond applications. Regardless, the support vias 208 absorb stresses from the pads 210 and prevent delamination. Different numbers, sizes and configurations of vias 210 may be provided around a contact pad 210, depending on how much stress on the pad 210 is to be dissipated by the via(s) 208.

A further embodiment of the support vias are shown in FIG. 8A. In this embodiment, the via pads 216 are omitted from the support vias 208. The support vias 208 are drilled and plated as described above, and then the contact pad 210 is formed directly over and around one or more associated support vias 208. The plating of the one or more support vias 208 lies in contact with an associated contact pad 210 to maintain the contact pad 210 on the core 203 and prevent delamination.

Referring again to FIG. 2, the signal carrier medium 202 may next be inspected in an automatic optical inspection (AOI) in step 104. Once inspected, a solder mask 220 may be applied to the signal carrier medium 202 in step 106. The solder mask is a layer of polymer that provides a protective coating for the electrical traces 212 of the conductance pattern and prevents solder from bleeding beyond the exposed contact pads 210, thereby preventing short circuits. FIGS. 9 and 10 show top and edge views of the signal carrier medium 202 including solder mask layer 220 on the top and/or bottom of the signal carrier medium 202. The application of the solder mask layer may be performed by methods including silk screening and photolithography.

After formation of the solder mask layer 220, the contacts pads 210 left exposed through the solder mask may be plated with a Ni/Au or the like in step 112 in a known electroplating or thin film deposition process. In step 116, the signal carrier medium 202 may then be inspected and tested in an automated inspection process, and in step 120, the signal carrier medium 202 may undergo a final visual inspection, to check for contamination, scratches and discoloration.

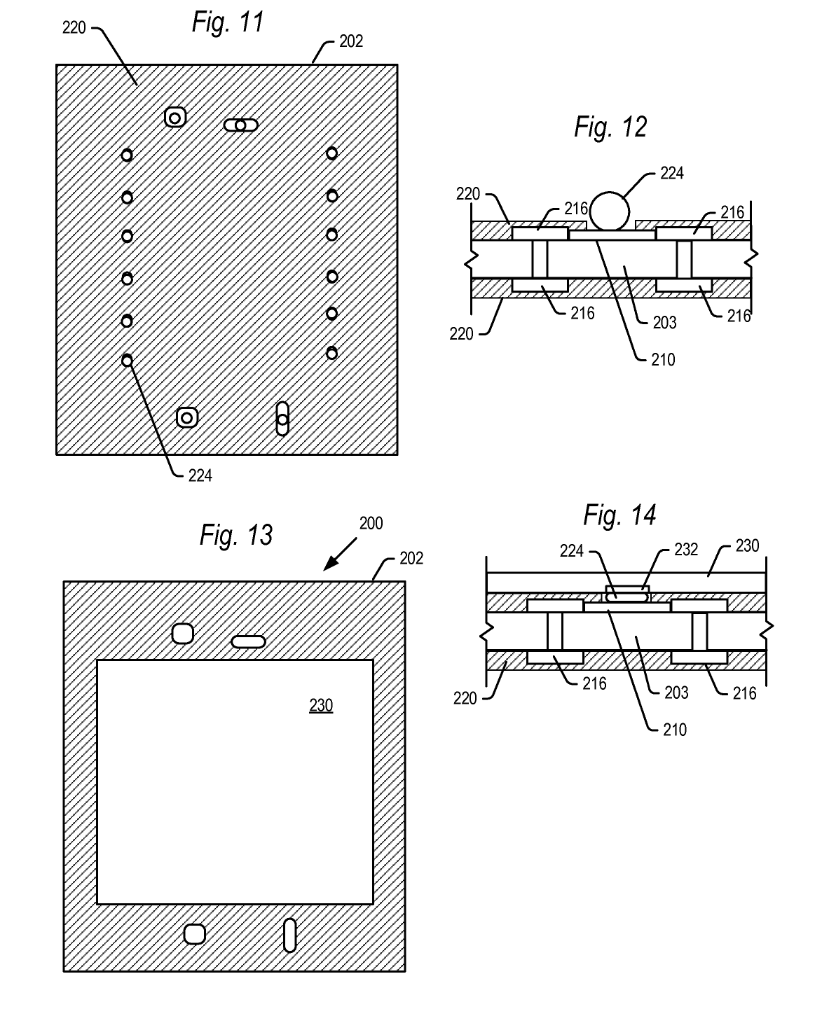

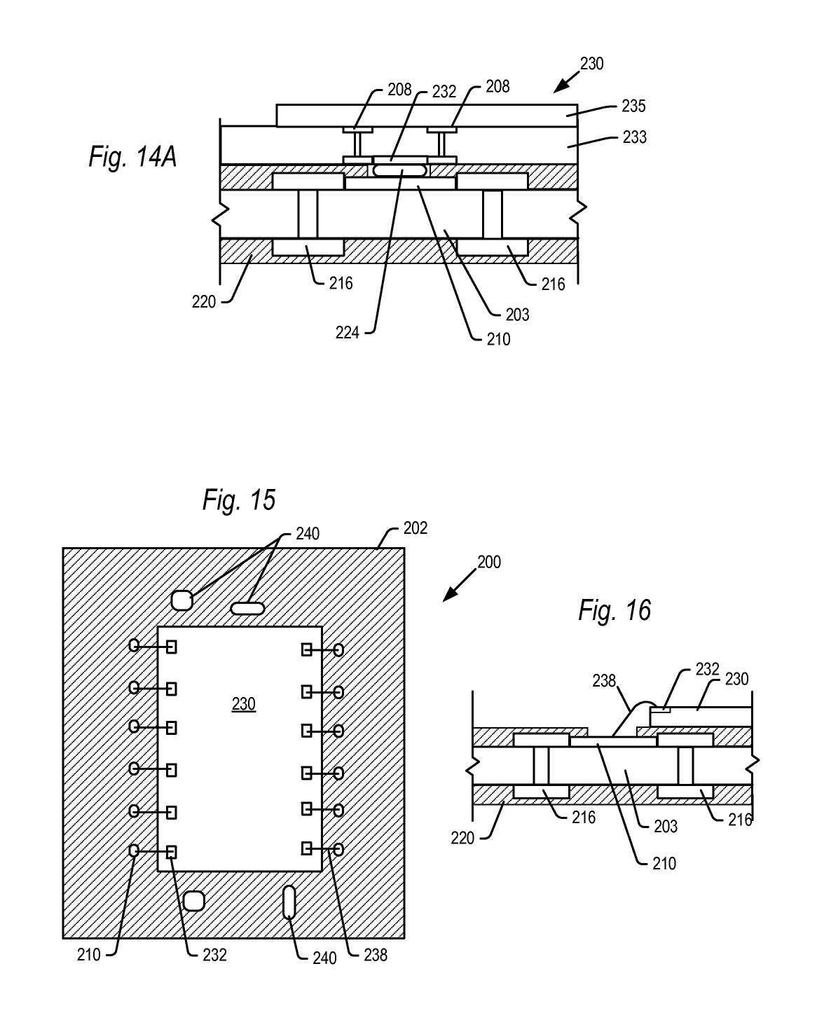

Assuming the signal carrier medium 202 passes inspection, in one embodiment, solder balls 224 may be affixed to the contact pads 210 in step 122, as shown in the top and cross-sectional views of FIGS. 11 and 12. The solder balls 224 may be used to affix surface mounted components, such as for example a flash memory semiconductor package which may be a BGA (ball grid array) or other package. For example, the top and cross-sectional views of FIGS. 13 and 14 show an electronic component 230 mounted to the signal carrier medium 202 in a step 124. The electronic component 230 may include a plurality of terminals 232 which are electrically coupled to the contact pads 210 via the solder balls 224. The signal carrier medium 202 and electronic component 230 may be heated in a reflow process in step 126 to melt the solder ball 224 which then hardens to permanently affix respective terminals 232 to contact pads 210.

The example of FIG. 14A is similar to the example of FIG. 14, where the electronic component 230 is a flash memory semiconductor device including a substrate 233 supporting one or more semiconductor die 235. The substrate 233 may include one or more terminals 232, and one or more support vias 208 for supporting terminals 232 in accordance with any of the embodiments described herein. The support vias 208 in the substrate 233 may include pads 216 as described above. The substrate 233 may include terminals 232 on a top surface of the substrate, which are supported by support vias 208 as described herein. The embodiment of FIG. 14A includes a signal carrier medium having a support via 208 carrying an electronic component including a support via 208.

One or more semiconductor die 235 may be mounted to the substrate 233 using the above-described steps. In embodiments, the one or more semiconductor die 235 may for example be a flash memory chip (NOR/NAND) and/or a controller die such as an ASIC. Other types of memory die are contemplated. One or more passive components such as resistors, capacitors and/or inductors may also be affixed and electrically coupled to the substrate 233.

Referring now to the top and cross-sectional views of FIGS. 15 and 16, as an alternative to surface mounting electronic component 230 to the signal carrier medium 202 via solder balls 224, the electronic component may be affixed to the contact pads 210 of the signal carrier medium 202 via wire bonds 238. While the terminals 232 are shown on opposed sides of the electronic component 230 in FIG. 15, it is understood that the terminals 232 and wire bonds 238 may be on a single side of the electronic component 230, two adjacent sides of the component 230, three sides or all four sides of the component 230.

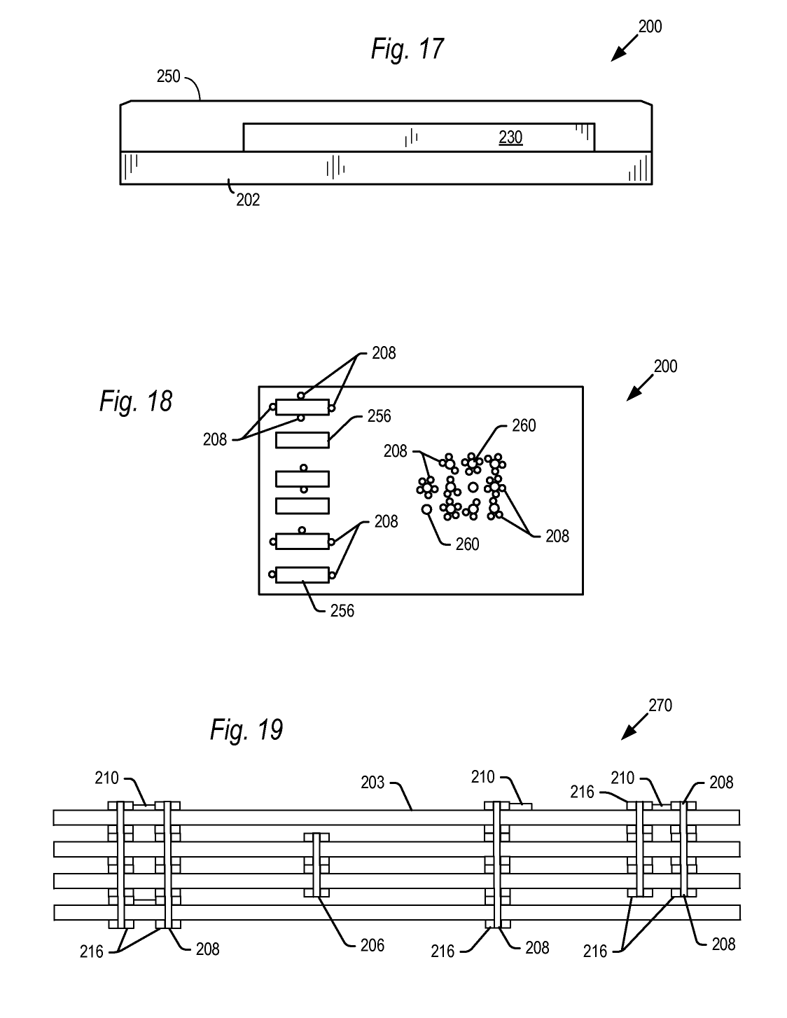

The electronic component 230 mounted on signal carrier medium 202 may form (or may form part of) a semiconductor device 200. In step 128, the semiconductor device 200 may undergo a plasma clean process to remove particulate. In step 130, the device may be encapsulated in a molding compound 250 (FIG. 17) to cover at least the electronic component 230 and contact pads 210. After encapsulation, the semiconductor device 200 may be singulated in step 134 to form the finished semiconductor device 200 shown for example in FIG. 17. Each device 200 may be singulated by any of a variety of cutting methods including sawing, water jet cutting, laser cutting, water guided laser cutting, dry media cutting, and diamond coating wire cutting. While straight line cuts will define a generally rectangular or square shaped device 200, it is understood that device 200 may have shapes other than rectangular and square in further embodiments of the present invention.

Once cut into devices 200, the devices may be tested in a step 136 to determine whether the devices are functioning properly. As is known in the art, such testing may include electrical testing, burn in and other tests. The devices may optionally be encased within a lid in step 140.

Semiconductor device 200 may be configured for one of a variety of different applications, including for example a non-volatile semiconductor memory device such as a flash memory storage card or device. Such devices include but are not limited to an SD Card, a Compact Flash, a Smart Media, a Mini SD Card, an MMC, an xD Card, a Transflash or a Memory Stick and an SD-USB combination memory device. Other devices are contemplated.

In the embodiments described above, the support vias 208 were provided around contact pads 210 used to connect electronic components 230. However, the support vias 208 may be used to prevent delamination of other metal pads. For example, FIG. 18 shows the bottom surface of a semiconductor device 200. Where device 200 is an LGA (land grid array) package, the device 200 may include a number of contact fingers 256 used to removably mate with pins in a host device (not shown) when the device 200 is inserted into the host device. One, two, three or all four of the sides of a contact finger 256 may include a support via 208 formed as described above (including via pads 216 or not). A single side may have one or more than one support via 208.

FIG. 18 further shows a number of test pads 260. As is known in the art, test pads may be used for electrical test of a device 200. In a further embodiment, the test pads 260 may also be prevented from delamination as a result of being surrounded (or partially surrounded) by one or more vias 208 (including via pads 216 or not). The number of support vias 208 surrounding a test pad 260 (or other metal pads described herein) may vary from none to five, though it may be more than five in further embodiments. In further embodiments, it is contemplated that one or more support vias 208 may additionally or alternatively be placed adjacent an electrical trace 212 (FIG. 5) to alleviate stress which may build in the electrical trace and prevent delamination of the electrical trace.

In embodiments described above, signal carrier medium 202 is shown as a single layer substrate, including a single core layer 203 surrounded by metal layers 204, 205. However, as noted, the signal carrier medium may be a multilayer substrate 270, as shown for example in the cross-sectional view of FIG. 19. Multilayer signal carrier medium 270 may include a plurality of dielectric cores 203, and a plurality of metal layers, one or more of which may be etched to conductance patterns. Signal communication vias 206 and/or support vias 208 may also be provided. As shown in FIG. 19, a support via 208 may be drilled through each of the layers of the multilayer signal carrier medium 270, or less than all of the layers. Via pads 216 may or may not be formed around a support via 208.

In summary, in one embodiment, the present technology relates to a signal carrier medium for a semiconductor device, comprising: a dielectric core; a metal portion on a surface of the dielectric core; and one or more support vias adjacent the metal portion, the support vias dissipating stresses within the metal portion.

In a further embodiment, the present technology relates to a semiconductor device, comprising: a signal carrier medium, including: a dielectric core, a metal portion on a surface of the dielectric core, and one or more support vias adjacent the metal portion, the support vias dissipating stresses within the metal portion; and a semiconductor die electrically coupled to the signal carrier medium.

In a further embodiment, the present technology relates to a signal carrier medium for a semiconductor device, comprising a plurality of dielectric core layers; a plurality of metal layers on at least one of a top and bottom surface of the plurality of dielectric core layers, a metal layer of the plurality of metal layers including a metal portion; and one or more support vias adjacent the metal portion, the support vias dissipating stresses within the metal portion.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

I claim:

1. A signal carrier medium for a semiconductor device, comprising:
a dielectric core;
a metal portion on a surface of the dielectric core; and
one or more support vias adjacent the metal portion, the support vias dissipating stresses within the metal portion.

2. A signal carrier medium as recited in claim 1, wherein the metal portion is a contact pad.

3. A signal carrier medium as recited in claim 2, wherein the contact pad receives a solder ball.

4. A signal carrier medium as recited in claim 2, wherein the contact pad receives a wire bond.

5. A signal carrier medium as recited in claim 1, wherein the metal portion is a contact finger.

6. A signal carrier medium as recited in claim 1, wherein the metal portion is a test pin.

7. A signal carrier medium as recited in claim 1, wherein the metal portion is an electrical trace.

8. A signal carrier medium as recited in claim 1, wherein the one or more support vias are formed completely through the dielectric core.

9. A signal carrier medium as recited in claim 1, wherein the one or more support vias are formed partially through the dielectric core.

10. A signal carrier medium as recited in claim 1, wherein the one or more support vias comprise between one and five support vias.

11. A signal carrier medium as recited in claim 1, wherein a support via of the one or more support vias includes a via pad around the support via on the surface of the dielectric core, the via pad lying in contact with the metal portion.

12. A signal carrier medium as recited in claim 1, wherein the metal portion is formed around a support via of the one or more support vias.

13. A signal carrier medium as recited in claim 1, further comprising a layer of solder mask which covers the support via and leaves the metal portion exposed.

14. A signal carrier medium as recited in claim 1, further comprising signal communication vias for communicating signals to different layers of the signal carrier medium.

15. A semiconductor device, comprising:
a signal carrier medium, including:
a dielectric core,
a metal portion on a surface of the dielectric core, and
one or more support vias adjacent the metal portion, the support vias dissipating stresses within the metal portion; and
a semiconductor die electrically coupled to the signal carrier medium.

16. A semiconductor device as recited in claim 15, wherein the metal portion is a contact pad.

17. A semiconductor device as recited in claim 16, wherein the semiconductor die includes a die bond pad facing the signal carrier medium, the contact pad receives a solder ball for electrically coupling the contact pad to the die bond pad.

18. A semiconductor device as recited in claim 16, wherein the semiconductor die includes a die bond pad facing away from the signal carrier medium, the semiconductor device further including a wire bond coupled to and extending between the contact pad and the die bond pad.

19. A semiconductor device as recited in claim 15, wherein the one or more support vias dissipate mechanical and thermal stresses from the metal portion.

20. A semiconductor device as recited in claim 15, wherein the one or more support vias are formed completely through the dielectric core.

21. A semiconductor device as recited in claim 15, wherein the one or more support vias are formed partially through the dielectric core.

22. A semiconductor device as recited in claim 15, wherein a support via of the one or more support vias includes a via pad around the support via on the surface of the dielectric core, the via pad lying in contact with the metal portion.

23. A semiconductor device as recited in claim 15, wherein the metal portion is formed over and around a support via of the one or more support vias.

24. A semiconductor device as recited in claim 15, wherein the semiconductor device is a flash memory device.

25. A signal carrier medium for a semiconductor device, comprising:
a plurality of dielectric core layers;
a plurality of metal layers on at least one of a top and bottom surface of the plurality of dielectric core layers, a metal layer of the plurality of metal layers including a metal portion; and
one or more support vias adjacent the metal portion, the support vias dissipating stresses within the metal portion.

26. A signal carrier medium as recited in claim 25, wherein the metal portion is a contact pad.

27. A signal carrier medium as recited in claim 25, wherein a first support via of the one or more support vias is formed through the entire signal carrier medium.

28. A signal carrier medium as recited in claim 27, wherein a second support via of the one or more support vias is formed partially through the signal carrier medium.
